(19) United States
(12) Patent Application Publication
(10) Pub. No.: US 2020/0208257 A1
(43) Pub. Date: Jul. 2, 2020

(54) COATING WITH DIAMOND-LIKE CARBON BY MEANS OF A PECVD MAGNETRON METHOD

(71) Applicant: SAINT-GOBAIN GLASS FRANCE, COURBEVOIE (FR)

(72) Inventors: Jan HAGEN, BONN (DE); Norbert HUHN, HERZOGENRATH (DE); Julian LINGNER, HERZOGENRATH (DE)

(21) Appl. No.: 16/633,751

(22) PCT Filed: Jul. 19, 2018
(86) PCT No.: PCT/EP2018/069609

§ 371 Date: Jan. 24, 2020

(30) Foreign Application Priority Data
Jul. 26, 2017 (EP) 17183187.8

(51) Int. Cl. C23C 14/35; C23C 14/34; C23C 14/06; C23C 14/02; C23C 14/00

(52) U.S. Cl. CPC C23C 14/35; C23C 14/3414; C23C 14/0063; C23C 14/024; C23C 14/0057; C23C 14/0611

(57) ABSTRACT

A method for coating a substrate with a diamond-like carbon (DLC) layer using a PECVD method with plasma generation by a magnetron target (magnetron PECVD) in a vacuum chamber, in which the magnetron, which is provided with the target, and the substrate are arranged, includes introducing at least one reactant gas into the plasma generated by the magnetron target in the vacuum chamber, as a result of which fragments of the reactive gas are formed, which are deposited forming the DLC layer on the substrate.

The invention relates to a method for producing layers made of diamond-like carbon (DLC) by a combined plasma-enhanced chemical vapor deposition (PECVD)/magnetron method (magnetron PECVD method).

For many applications, it is desirable to provide a substrate surface with improved scratch resistance. For example, float glass inherently does not have high scratch resistance; however, the application of a suitable thin film can significantly improve the scratch resistance of the glass surface.

Thin layers made of diamond-like carbon (DLC) are particularly well suited for that and their scratch resistance is well known. Industrial methods for applying DLC layers on glass panes are known from the patent literature.

For example, CN 105441871 A describes the production of superhard DLC layers using PVD and HIPIMS methods. CN 104962914 A describes an industrial vapor deposition device for depositing DLC layers. Another device for producing DLC layers is described in CN 203834012 U. JP 2011068940 A relates to a method for producing abrasion-resistant DLC layers.

WO 2004/071981 A2 relates to an ion beam technique for depositing DLC layers on glass. This technique delivers layers of good quality, but is demanding in terms of process stability. In particular, the accumulation of material (DLC material) on the ion source can adversely affect the operating stability of the ion source and result in process interruptions, for example, due to problems with the electrical insulation, arcing, accumulations, etc.

Other customary methods for DLC deposition such as chemical vapor deposition (CVD) are unsuitable for large-scale coatings on glass since they require high deposition temperatures and for industrial engineering reasons cannot be easily scaled up for large surfaces. The heating of large glass panes is very expensive in terms of energy consumption and risky because of possible glass breakage.

Other methods for depositing DLC layers are disclosed in DE 34 42 208 A1, DE 10 2010 052971 A1, DE 197 40 793 A1, and U.S. Pat. No. 5,268,217 A.

The object of the invention is to overcome the above-described disadvantages of the prior art. The object consists, in particular, in providing a method for coating substrates with DLC layers that is suitable for the large-scale coating of substrates, such as glass panes, and delivers DLC layers with mechanical properties, in particular in terms of scratch resistance, and optical properties that are comparable to those achieved by prior art ion beam techniques or CVD methods, but avoid the problems associated with these prior art techniques. In particular, the method should improve process stability and not require heating of the substrate. Moreover, the method should be implemented with existing common deposition devices.

According to the invention, this object is accomplished by a coating method according to claim 1. The invention also relates, according to the other claim, to a coated substrate that is obtainable according to the coating method according to the invention. Preferred embodiments of the invention are reported in the dependent claims.

The invention thus relates to a method for coating a substrate with a diamond-like carbon (DLC) layer using a PECVD method with plasma generation by means of a magnetron target (magnetron PECVD) in a vacuum chamber, in which the magnetron provided with the target and the substrate are arranged, wherein the method includes introducing at least one reactant gas into the plasma generated by the magnetron target in the vacuum chamber, as a result of which fragments of the reactive gas are formed, which are deposited on the substrate to form the DLC layer.

It has surprisingly been found that DLC coatings of excellent quality in terms of scratch resistance were obtained by the magnetron PECVD method used according to the invention, which coatings have mechanical properties comparable to DLC thin layers that are obtained with ion source techniques or CVD. The magnetron target material is not appreciably incorporated into the DLC thin layers formed and, consequently, does not alter the layer properties, in particular in terms of the optical properties, with, if desired, even doping of the DLC layer by the target material being optionally possible.

Moreover, the magnetron PECVD method requires no heating of the substrate and is, consequently, suitable for large-scale deposition on glass or other temperature-sensitive substrates. The method according to the invention can be realized with conventional deposition devices.

The invention is explained in the following description and with reference to the attached figures. They depict:

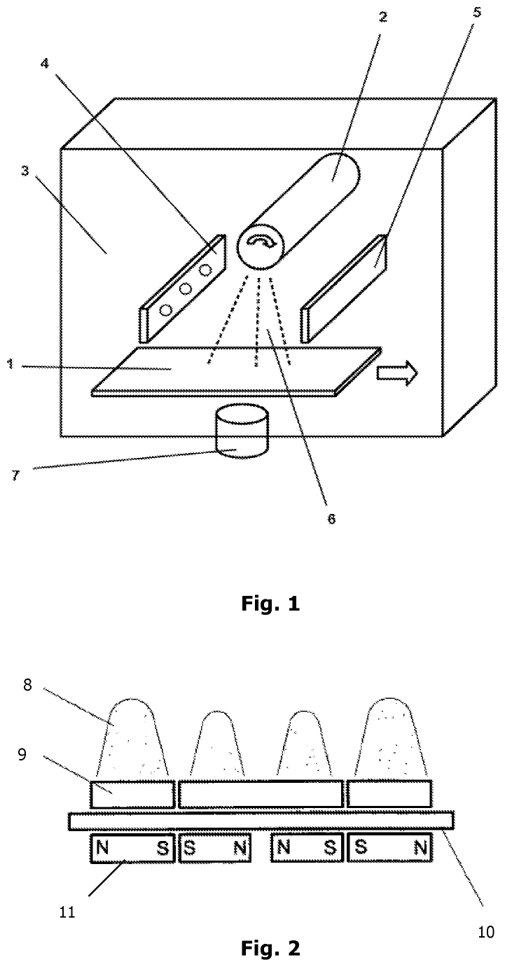

FIG. 1 a schematic representation of the structure of a device for carrying out the magnetron PECVD method according to the invention;

FIG. 2 a schematic representation of a planar magnetron;

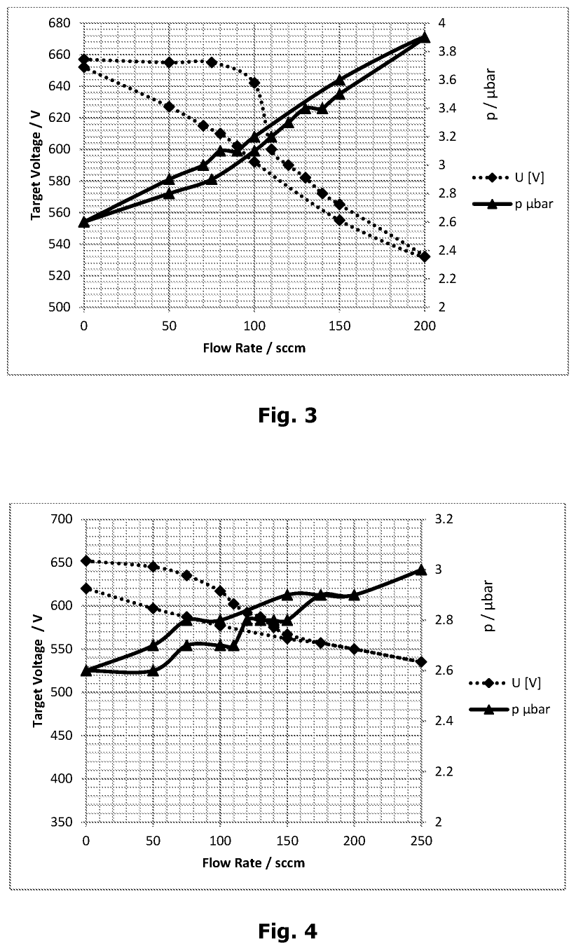

FIG. 3 a PECVD magnetron hysteresis curve for target voltage and pressure as a function of the flow rate of the reactant;

FIG. 4 a PECVD magnetron hysteresis curve for target voltage and pressure as a function of the flow rate of the reactant.

The method according to the invention for coating the substrate with a diamond-like carbon (DLC) layer is a PECVD method, in which the plasma is generated by a magnetron or a magnetron target. Such methods are, in principle, known and are, for example, referred to as magnetron-enhanced PECVD, magnetron PECVD, or PECVD magnetron methods.

Plasma-enhanced chemical vapor deposition is a known chemical vapor deposition method and PECVD is used as an abbreviation for it. PECVD is a special form of chemical vapor deposition (CVD), in which the chemical deposition is supported by a plasma.

In CVD methods such as PECVD, a solid component is deposited on a substrate out of the vapor phase due to chemical reactions. The molecules of the reactant gas are decomposed or dissociated by means of heat or energy input with the formation of fragments. These fragments can be active species such as excited atoms, radicals, or ions that are deposited on the substrate to form the solid layer, in this case, the DLC layer. In contrast to the CVD method, in the physical vapor deposition method (PVD), a material vapor is deposited on the substrate.

In contrast to conventional CVD methods, in which the energy input for the reaction or dissociation of the reactants is done thermally, in the PECVD method, the energy required for the reaction is provided by a plasma, which enables deposition even at lower temperatures. This has the advantage that even temperature-labile substrates can be coated.

According to the invention, the plasma for the PECVD method is generated by a magnetron or a magnetron target. Magnetrons comprise electrodes and a magnet assembly. The cathode, typically in the form of a cathode tube or a planar body, is usually referred to as a target or magnetron target, wherein, usually, an additional material is attached to the cathode and serves as a target or magnetron target. The magnetron assembly is situated behind the target based on its positioning relative to the substrate.

All conventional, known embodiments of the magnetron can be used as a magnetron for generating plasma. The target can, for example, be a planar target or a rotatable target, with a rotatable target being preferred. Magnetrons with such targets are commercially available. Magnetrons with planar targets can include a magnet assembly, which magnetrons are attached in a fixed position behind the target. In a magnetron with a rotatable target, a target, which is usually tubular, surrounds a magnet assembly, wherein the target is rotatably mounted and drivable, wherein the magnet assembly is usually unmovable, i.e., does not rotate.

The magnetron plasma source is generated by the magnetron target. In a preferred embodiment, the magnetron target is a target made of silicon, carbon, or a metal, with the metal preferably selected from titanium, zirconium, hafnium, vanadium, niobium, tantalum, chromium, molybdenum, or tungsten.

The target is particularly preferably made of silicon or titanium. The silicon target can be doped with aluminum and/or boron and/or zirconium and/or hafnium and/or titanium. This can be advantageous in order to improve the target conductivity or the process stability of the deposition.

In the method according to the invention, the magnetron provided with the target and the substrate to be coated are arranged in a vacuum chamber. During operation, power is applied to the target in order to generate a plasma in the vacuum chamber by the magnetron or the magnetron target. The target and the substrate are positioned such that the plasma is formed between the target and the substrate.

One or a plurality of magnetrons provided with the target can be arranged in the vacuum chamber. The substrate and/or the magnetron can be displaceably arranged, in order to enable different positioning, as is customary in such devices. Customary vacuum coating systems, for example, commercial vacuum sputtering apparatuses, can be used for the method according to the invention.

Suitable as reactants that are fed as reactant gas into the vacuum chamber or into the plasma, are, for example, liquids and gases; however, even solids are conceivable if they can be converted into the vapor phase. Liquids can be converted into the vapor phase before introduction into the vacuum chamber by heating and/or using a carrier gas, e.g., argon.

According to a preferred embodiment, reactants that contain or are made of the elements carbon and hydrogen or the elements silicon, carbon, and hydrogen are suitable. The at least one reactant is preferably selected from hydrocarbons, organosilicon compounds, or mixtures thereof. Organosilicon compounds are preferably silicon compounds that include hydrocarbon radicals, such as alkyl groups. When organosilicon compounds are used, the DLC layer formed can be doped with silicon.

In a preferred embodiment, the at least one reactant is selected from tetramethylsilane (TMS), C₁-C₁₀-alkanes, C₂-C₁₀-alkynes, benzene, or mixtures thereof. Examples of C₂-C₁₀-alkynes are ethyne, propyne, butyne, pentyne, hexyne, heptyne, octyne, nonyne, decyne, and their isomers. Examples of C₁-C₁₀-alkanes are methane, ethane, propane, butane, pentane, hexane, heptane, octane, nonane, decane, and their isomers. The at least one reactant is particularly preferably selected from tetramethylsilane (TMS), methane (CH₄), ethyne (C₂H₂), or combinations thereof.

It is also possible to use reactants that contain elements other than Si, C, and H, e.g., nitrogen, sulfur, fluorine, or chlorine. Such reactants can be advantageous for modifying the wetting properties or the mechanical properties of the DLC layer. This can result from doping the DLC layers with elements other than carbon and hydrogen, which are contained in such reactants.

Elements other than carbon and hydrogen are also referred to here as foreign atoms. The DLC layers produced according to the method of the invention can be doped with one or a plurality of such foreign atoms. The expression “foreign atoms” makes no statement as to the bonding conditions of these foreign atoms in the DLC layer in which they are incorporated. The doping of the DLC layer with foreign atoms can be used selectively to modify the properties of the DLC layer.

Reactants that contain elements different from Si, C, and H can, optionally be used alone if they also include carbon and, optionally, hydrogen. However, it is usually preferred to use these reactants in combination with at least one reactant that is selected from hydrocarbons and/or organosilicon compounds, as described above, this being required, of course, for reactants that contain no carbon and, optionally, hydrogen.

A reactant that contains elements different from Si, C, and H is, for example, nitrogen (N₂-gas), that, optionally, can be allowed into the vacuum chamber as additional components together with reactants such as hydrocarbons or organosilicon compounds as reactant gas. Of course, it is also possible to introduce it into the vacuum chamber separately from the at least one other reactant gas. Here, N₂-gas is usually not an inert gas.

Reactants that contain fluorine constitute another example. These can be advantageous since the hydrophobicity of the DLC layer can be affected thereby. Suitable optional fluorine-containing reactants are perfluorocarbons, such as tetrafluoromethane (CF₄) or perfluorooctane. Also, fluorine-containing reactants are, when used, commonly used as additional reactants together with hydrocarbons and/or organosilicon compounds.

The method according to the invention includes introducing one or a plurality of reactant gases into the vacuum chamber and, thus, into the plasma formed by the magnetron target. When using multiple reactant gases, they can be introduced separately or as a mixture. The usual feed systems are used for the introduction of the reactant gases. The reactant gases are subjected, in the plasma, to the above-described chemical reactions, by means of which fragments of the reactive gas are formed, which fragments are deposited on the substrate forming the DLC layer.

In a preferred embodiment, the method according to the invention further includes introducing at least one inert gas into the vacuum chamber. Examples of preferred inert gases are neon, argon, krypton, xenon, or a combination thereof. The inert gas can, for example, be useful to enhance plasma generation.

In a particularly advantageous embodiment of the method according to the invention, the ratio of the flow rates of reactive gas/inert gas is >0.4, preferably >0.5, and particularly preferably >0.6.

In another advantageous embodiment of the method according to the invention, the reactant gas is C₂H₂, CH₄, or TMS and the inert gas Ar, in other words, the ratio of the flow rates of C₂H₂/Ar or CH₄/Ar or TMS/Ar is >0.4, preferably >0.5, and particularly preferably >0.6. With such ratios, it was possible to produce particularly scratch resistant coatings. Of course, mixtures of C₂H₂, CH₄, or TMS can also be used.

In a particularly preferred embodiment of the method according to the invention, the magnetron PECVD method is operated such that during the deposition of the DLC layer onto the substrate, the target is operated in poisoned mode. This surprisingly yields better mechanical properties of the DLC layers formed.

The phenomenon of target poisoning is well known to the person skilled in the art. Instead of the expression “target in poisoned mode”, the phenomenon is also often referred to as “poisoned target”, “target in the poisoned state”, “poisoned mode”. Without intending to subscribe to a theory, this is presumably caused substantially by a complete covering of the target with reactant gas. Target poisoning causes enveloping of the deposition process, which can be evident from more or less significant sudden changes in process parameters, such as deposition rates, partial pressure of the reactant gas, or target voltage. It is also said that the process tips from the metallic into the poisoned mode. This also becomes noticeable in that the process parameters present hysteresis behavior.

Usually, target poisoning is detrimental to the process since, in particular, the deposition rate decreases, which is why operating the method in such a way that the target is in poisoned mode is usually avoided. It was all the more surprising that the operation of the method according to the invention with a target in poisoned mode yielded significantly better results. The best DLC properties were obtained in the region of the target poisoning.

The person skilled in the art is readily capable of operating such methods by appropriate adjustment of the process parameters such that the target is in poisoned mode. This can also be controlled using the above-described behavior of process parameters in terms of change and hysteresis.

As is known to the person skilled in the art, the operation of the method with the target in poisoned mode can be achieved, for example, by appropriate adjustment, in particular an increase in the flow rate of the reactant gas(es), i.e., an increase in the amount of reactant in the vacuum chamber. For this, a specific method can be customized, for example, hysteresis curves of process parameters, for example, of the target voltage and/or of the vacuum pressure, as a function of the flow rate of the reactant(s). The area, in which there is target poisoning, is situated in the diagram to the right of the hysteresis curve, i.e., in the direction of the higher flow rates. Process control should thus be done to the right of the hysteresis curve, i.e., outside the hysteresis range in order to operate the target in poisoned mode.

Since flow rates are highly dependent on the geometry, pump rate, etc. of the coating system, the appropriate flow rate for target poisoning can be determined meaningfully for each specific case.

In a preferred embodiment of the method according to the invention, the temperature of the substrate, in particular of a glass substrate, during the deposition of the DLC layer is in the range from 20° C. to 150° C.

The method according to the invention is carried out in a vacuum in the vacuum chamber. In a preferred embodiment, the pressure in the vacuum chamber is in the range from 0.1 pbar to 10 pbar.

The power applied to the target/target length during the method according to the invention can, for example, be in the range from 1 kW/m to 50 kW/m, preferably from 5 kW/m to 25 kW/m.

The deposition rate of DLC can, for example, be in the range from 1 nm*m/min to 200 nm*m/min, preferably from 10 nm*m/min to 100 nm*m/min.

The substrate can be a conductive substrate or a nonconductive substrate. Preferred substrates are substrates made of metal, plastic, paper, glass, glass ceramic, or ceramic. In a particularly preferred embodiment, the substrate is made of glass, for example, in the form of a glass pane. A preferred glass substrate is float glass. The thickness of the substrate, in particular the glass substrate, can vary within wide ranges, wherein the thickness can be, for example, in the range from 0.1 mm to 20 mm.

The substrate can be uncoated or be pre-coated with at least one base layer. When using a pre-coated substrate, the DLC layer is applied on this pre-coating. In a preferred embodiment of the invention, the substrate is an uncoated glass substrate or a glass substrate pre-coated with a base layer.

The pre-coating used as a base layer for the substrate, in particular a glass substrate, can be a material selected from silicon carbide, silicon oxide, silicon nitride (Si₃N₄), silicon oxynitride, metal oxide, metal nitride, metal carbide, or contain a combination thereof or be made thereof, with Si₃N₄ and/or doped Si₃N₄ preferable and Si₃N₄ doped with Zr, Ti, Hf, and/or B particularly preferable. In the case of metal oxides, metal nitrides, and metal carbides, the metal can be, for example, titanium, zirconium, hafnium, vanadium, niobiumium, tantalum, chromium, molybdenum, or tungsten.

For producing the base layer, vapor deposition methods such as PVD, in particular sputtering, preferably magnetron sputtering, CVD, or ALD, can be used. The base layer has, for example, a layer thickness from 1 nm to 100 nm, preferably from 5 nm to 50 nm.

By means of the method according to the invention, a DLC layer is obtained on the substrate with excellent optical and mechanical properties. In a preferred embodiment, the DLC layer has a layer thickness from 1 nm to 100 nm, preferably 1 nm to 50 nm, more preferably 1 nm to 20 nm, particularly preferably from 2 nm to 10 nm, in particular from 3 nm to 8 nm.

Layers made of diamond-like carbon are generally known. Diamond-like carbon is usually abbreviated to DLC. In DLC layers, hydrogen-free or hydrogen-containing amorphous carbon is the predominant constituent, wherein the carbon can consist of a mixture of sp³ and sp² hybridized carbon; optionally, sp³ hybridized carbon or sp² hybridized carbon can predominate. Examples of DLC are those with the designation ta-C and a:C—H. The DLC layer used according to the invention can be doped or undoped.

In a preferred embodiment, the DLC layer formed can be doped with at least one foreign atom, with the foreign atom preferably selected from silicon, oxygen, sulfur, nitrogen, chlorine, fluorine, or a metal, with the metal preferably selected from titanium, zirconium, hafnium, vanadium, niobium, tantalum, chromium, molybdenum, or tungsten.

The foreign atoms can be introduced into the DLC layer, for example, through the use of a reactant that contains the foreign atom, as already explained above. Metals and silicon as foreign atoms can, optionally, be introduced into the DLC layer via corresponding targets made of this material.

The invention also relates to the coated substrate, in particular the coated glass substrate, that is obtainable through the method according to the invention as described above. The glass panes according to the invention are suitable, for example, for buildings, vehicles, glass furniture, e.g. shelves or tables, tactile applications, and screens.

The invention is further explained in the following with reference to nonrestrictive exemplary embodiments and the accompanying drawings.

FIG. 1 depicts a purely schematic representation of the structure of a device for carrying out the magnetron PECVD method according to the invention. A substrate 1, for example, a glass pane, and a magnetron with a rotatable target 2 in the form of the cylinder are arranged in the vacuum chamber 3. The target can, for example, be a silicon target. The substrate is displaceable. In operation, a plasma 6 is generated between substrate 1 and target 2 by the magnetron target. By means of the supply device for reactant gas 4, the reactant gas, for example, C₂H₂, and the plasma can be introduced into the vacuum chamber. By means of the supply device for inert gas 5, inert gas, for example, argon, can be introduced into the vacuum chamber as needed. The vacuum connection 7 serves to adjust the vacuum.

FIG. 2 depicts a schematic representation of a planar magnetron 10, which has a target 9 mounted on the cathode and a magnet assembly 11 positioned below it. The resultant magnetic field 8 is sketched schematically.

### EXAMPLES

With a device corresponding to FIG. 1, magnetron hysteresis curves for various reactants in combination with a silicon target were tested. Argon was used as the inert gas. DLC layers were produced on glass substrates using the magnetron PECVD method. The best DLC properties were obtained in the region of the target poisoning.

FIG. 3 shows the PECVD magnetron hysteresis curve for a silicon target and CH₄ as a reactant, in which the process parameters target voltage and pressure were recorded as a function of the flow rate of the reactant.

FIG. 4 shows the PECVD magnetron hysteresis curve obtained for a silicon target and C₂H₂ as a reactant, in which the process parameters target voltage and pressure were recorded as a function of the flow rate of the reactant.

The process parameters that were selected for the deposition of the DLC thin layers are shown in the following Table 1. The equipment used is a conventional magnetron coating apparatus.

TABLE 1
Deposition parameters for DLC coatings
by PECVD magnetron methods

| | Ar - | C₂H₂ - | Si- | Deposition | Layer |
|---|---|---|---|---|---|
| | flow rate/ | flow rate/ | Target | rate/ | thickness/ |
| | sccm | sccm | power/kW | nm*m*min⁻¹ | nm |
| DLC1 | 300 | 75 | 12 | 17.3 | 20 |
| DLC2 | 300 | 75 | 12 | 17.3 | 50 |
| DLC3 | 300 | 200 | 12 | 22.5 | 20 |
| DLC4 | 300 | 200 | 12 | 22.5 | 50 |

The layer quality obtained is very reproducible and process stability is very good.

In further test series, it was found that particularly good scratch resistance could be achieved with ratios of the flow rates of C₂H₂/Ar of >0.4. This is, in particular, the case when the DLC layer had been applied on a glass substrate.

The performance achieved is reported in the following Table 2. It can be seen that the Examples DLC3 and DLC4, which were deposited in the poisoned target mode, had the best mechanical behavior and the lowest optical absorption.

TABLE 2

| Optical Properties | DLC1 | DLC2 | DLC3 | DLC4 |
|---|---|---|---|---|
| TL A | 84.6% | 71.6% | 88.8% | 85.0% |
| a*t D65 | −0.1 | +0.9 | −0.2 | −0.1 |
| b*t D65 | +4.5 | +8.3 | +2.0 | +4.3 |
| RLc A | 12.3% | 23.0% | 9.4% | 11.7% |
| a*c D65 | −0.9 | −2.2 | −0.4 | −1.0 |
| b*c D65 | −5.8 | −6.6 | −2.3 | +4.3 |
| Scratch resistance on glass | NOK | NOK | OK | OK |

The following parameters are listed. Light transmittance according to light type A: TL A, color values a*t and b*t per light type D65, light reflection on layer side per light type A: RLc A, color value layer side a*c and b*c per light type D65

DLC layers that are obtained with the PECVD magnetron technology can easily be combined with “conventional” magnetron coatings that are obtained with identical equipment. Si₃N₄-base layers as pre-coating on the substrate can be useful, for example, for further improving the optics and durability of DLC on glass.

### LIST OF REFERENCE CHARACTERS

1 substrate (displaceably arranged)
2 magnetron with rotatable target
3 vacuum chamber
4 supply device for reactant gas
5 supply device for inert gas (optional)
6 plasma
7 vacuum connection
8 magnetic field
9 target
10 magnetron
11 magnet arrangement

1. A method for coating a substrate with a diamond-like carbon layer using a PECVD method with plasma generation by means of a magnetron target in a vacuum chamber, in which the magnetron, which is provided with the target, and the substrate are arranged, comprising introducing at least one reactant gas into the plasma generated by the target in the vacuum chamber, as a result of which fragments of the reactive gas are formed, which are deposited forming the diamond-like carbon layer on the substrate, wherein the PECVD method with plasma generation by means of a magnetron target is operated such that during the deposition of the diamond-like carbon layer onto the substrate, the target is operated in poisoned mode.

2. The method according to claim 1, wherein the target is a target made of silicon, carbon, or a metal, wherein the metal is selected from titanium, zirconium, hafnium, vanadium, niobium, tantalum, chromium, molybdenum, or tungsten.

3. The method according to claim 2, wherein the silicon target is doped with aluminum and/or boron and/or zirconium and/or hafnium and/or titanium.

4. The method according to claim 1, wherein the target is a planar target or a rotatable target.

5. The method according to claim 1, wherein the at least one reactant is already present in the vapor phase before introduction into the vacuum chamber or is converted into the vapor phase by heating.

6. The method according to claim 1, wherein the at least one reactant is selected from hydrocarbons, organosilicon compounds, or mixtures thereof.

7. The method according to claim 1, wherein the at least one reactant is selected from tetramethylsilane, C₁-C₁₀-alkanes, C₂-C₁₀-alkynes, benzene, or mixtures thereof.

8. The method according to claim 1, further comprising introducing at least one inert gas into the vacuum chamber, wherein the inert gas is selected from neon, argon, krypton, xenon, or a combination thereof.

9. The method according to claim 1, wherein the ratio of the flow rates of reactive gas/inert gas is >0.4, and the reactant gas is C₂H₂, CH₄, or TMS and the inert gas is Ar.

10. The method according to claim 1, wherein the temperature of the substrate is in the range from 20° C. to 150° C. during the deposition of the diamond-like carbon layer.

11. The method according to claim 1, wherein the pressure in the vacuum chamber is in the range from 0.1 μbar to 10 μbar.

12. The method according to claim 1, in which the substrate is a conductive substrate or a nonconductive substrate, wherein the substrate is made of metal, plastic, paper, glass, glass ceramic, or ceramic.

13. The method according to claim 1, wherein the substrate is uncoated or is pre-coated with at least one base layer, wherein the substrate is an uncoated glass substrate or a glass substrate pre-coated with a base layer, wherein the base layer contains silicon nitride.

14. The method according to claim 1, wherein the diamond-like carbon layer formed is undoped or is doped with at least one foreign atom, wherein the foreign atom is selected from silicon, oxygen, sulfur, nitrogen, fluorine, or a metal, wherein the metal is selected from titanium, zirconium, hafnium, vanadium, niobium, tantalum, chromium, molybdenum, or tungsten.

15. Coated A coated substrate, obtainable by a method according to claim 1.

16. The method according to claim 9, wherein the ratio of the flow rates of reactive gas/inert gas is >0.5.

17. The method according to claim 16, wherein the ratio of the flow rates of reactive gas/inert gas is >0.6.

18. The method according to claim 10, wherein the substrate is a glass substrate.

19. The method according to claim 12, wherein the substrate is a glass substrate.
